(19) United States
(12) Patent Application Publication
(10) Pub. No.: US 2017/0125583 A1
(43) Pub. Date: May 4, 2017

(54) HIGH VOLTAGE TRANSISTOR WITH SHORTENED GATE DIELECTRIC LAYER

(71) Applicant: UNITED MICROELECTRONICS CORP., Hsin-Chu City (TW)

(72) Inventors: Shih-Yin Hsiao, Chiayi County (TW); Kun-Huang Yu, New Taipei City (TW)

(21) Appl. No.: 14/930,596

(22) Filed: Nov. 2, 2015

(51) Int. Cl. H01L 29/78; H01L 29/08; H01L 29/423; H01L 29/06; H01L 29/10

(52) U.S. Cl. CPC H01L 29/7816; H01L 29/0649; H01L 29/1095; H01L 29/42364; H01L 29/0869; H01L 29/0886; H01L 29/086; H01L 29/0878

(57) ABSTRACT

A high voltage transistor includes a substrate, a well which is disposed within the substrate, a gate disposed on the well, a gate dielectric layer disposed between the well and the gate, two drift regions respectively disposed in the well at two sides of the gate, two source/drain regions respectively disposed within each drift region, wherein a width of the gate dielectric layer is smaller than a width of the source/drain region, and two isolation elements respectively disposed within each drift region

### BACKGROUND OF THE INVENTION

1. Field of the Invention

The present invention relates to a high voltage transistor and a method of fabricating the same, and more particularly to a high voltage transistor wherein a width of the gate dielectric layer is smaller than a width of the source/drain region, and a method of fabricating the same.

2. Description of the Prior Art

An integrated circuit chip includes a logic function circuit and a power supply circuit. The logic function circuit is implemented by a complementary metal-oxide-semiconductor (CMOS) transistor, and the power supply circuit is implemented by a high voltage metal-oxide-semiconductor field-effect transistor. The conventional isolated high voltage metal-oxide-semiconductor field-effect transistor has some drawbacks. For example, the Kirk effect occurs as the operational voltage increases. Therefore, there is a need for an improved method to solve these drawbacks.

### SUMMARY OF THE INVENTION

According to a preferred embodiment of the present invention, a high voltage transistor, includes a substrate, a well which is disposed within the substrate, a gate disposed on the well, a gate dielectric layer disposed between the well and the gate, two drift regions respectively disposed in the well at two sides of the gate, two source/drain regions respectively disposed within each drift region, wherein a width of the gate dielectric layer is smaller than a width of the source/drain region, and two isolation elements respectively disposed within each drift region.

According to a preferred embodiment of the present invention, a high voltage transistor includes a substrate, an isolation region disposed within the substrate to define a region, a well which is disposed within the substrate, a gate disposed on the well and above the region, a gate dielectric layer overlapping the region and disposed between the well and the gate, two drift regions respectively disposed in the well at two sides of the gate and two source/drain regions respectively disposed within each drift region, wherein a width of the region is smaller than a width of the source/drain region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 depicts schematically a top view of a high voltage transistor according to a first preferred embodiment of the present invention.

FIG. 2 is a cross-sectional view taken along line A-A′ of the high voltage transistor in FIG. 1.

FIG. 3 shows a top view of high voltage devices with gate dielectric layers of different widths.

FIG. 4 is a graph of current density vs. operational voltage for high voltage transistors with gate dielectric layers of different widths.

FIG. 5 depicts schematically a top view of a high voltage transistor according to a second preferred embodiment of the present invention.

FIG. 6 is a cross-sectional view taken along line B-B′ of the high voltage transistor in FIG. 5.

### DETAILED DESCRIPTION

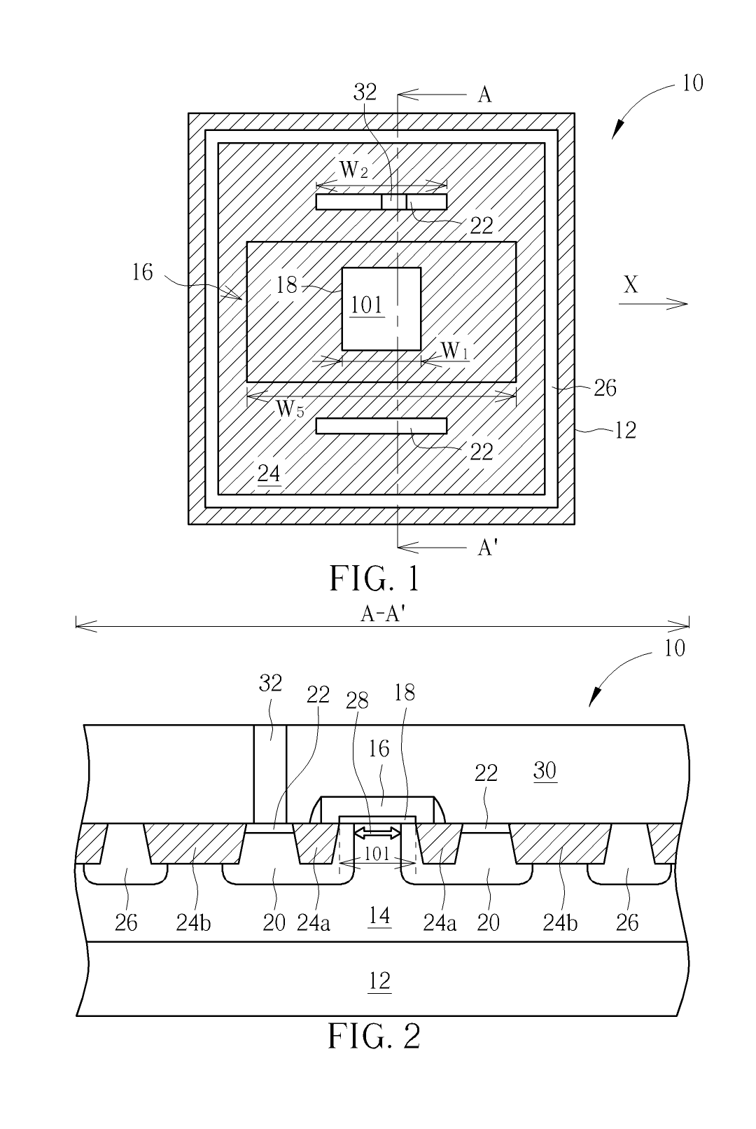

FIG. 1 depicts schematically a top view of a high voltage transistor according to a first preferred embodiment of the present invention. FIG. 2 is a cross-sectional view taken along line A-A′ of the high voltage transistor in FIG. 1. As shown in FIG. 1 and FIG. 2, a high voltage transistor 10 includes a substrate 12, a well 14 disposed within the substrate 12, and a gate 16 disposed on the well 14. The high voltage transistor 10 further includes a gate dielectric layer 18 disposed between the well 14 and the gate 16, two drift regions 20 respectively disposed in the well 14 at two sides of the gate 16, two source/drain regions 22 respectively disposed within each drift region 20, and isolation region 24 including two isolation elements 24a respectively disposed within each drift region 20. Slashes show the position of the isolation region 24. It is note-worthy that a width W₁ of the gate dielectric layer 18 is smaller than a width W₂ of the source/drain region 22. According to the preferred embodiment of the present invention, the width W₁ of the gate dielectric layer 18 is smaller than the width W₂ of the source/drain region 22 but not smaller than ⅓ of the width W₂ of the source/drain region 22. The isolation elements 24a may be shallow trench isolations. Another isolation region 24 such as two other isolation elements 24b is disposed within the well 14. Each of the isolation elements 24b partly overlaps one of the drift regions 20. The isolation elements 24b may be field oxides or shallow trench isolations. Each of the source/drain regions 22 is sandwiched between one of the isolation elements 24a and one of the isolation elements 24b. Each of drift regions 20 encloses one of the source/drain regions 22 and one of the isolation elements 24a. One pickup region 26 may be disposed at one side of each isolation element 24b. The pickup region 26 may be coupled to a ground voltage or a power supply voltage.

The substrate 12 may be a bulk silicon substrate, a germanium substrate, a gallium arsenide substrate, a silicon germanium substrate, an indium phosphide substrate, a gallium nitride substrate, a silicon carbide substrate, or a silicon on insulator (SOI) substrate. The well 14 is of a first conductive type. The drift regions 20 are of a second conductive type. The source/drain regions 22 are of the second conductive type. The pickup region 26 is of the first conductive type. The first conductive type is different from the second conductive type. The first conductive type is P conductive type while the second conductive type is N conductive type. In another example, the first conductive type is N conductive type while the second conductive type is P conductive type. The dopant concentration of the second conductive type in the drift regions 20 is smaller than a dopant concentration of the second conductive type in the source/drain regions 22. According to a preferred embodiment of the present invention, a dopant concentration of the second conductive type in the drift regions 20 is between 1E12˜8E12 cm⁻². A dopant concentration of the second conductive type in the source/drain regions 22 is between 1E14 and 1E15 cm⁻². When the high voltage transistor is activated, a current 28 is formed under the gate dielectric layer 18, and between the two drift regions 20. Moreover, the gate dielectric layer 18 can be made of silicon oxide. The gate includes at least one conductive material such as metal or polysilicon.

As shown in FIG. 1, the width W₂ of the source/drain region 22 extends along the same direction as the gate 16. The width W₁ of the gate dielectric layer 18 also extends along the same direction as the gate 16. For example, when the gate 16 extends along a direction X, the width W₂ of the source/drain region 22 also extends along the direction X. Moreover, the width W₁ of the gate dielectric layer 18 also extends along the direction X. There can be a dielectric layer 30 covering the high voltage transistor 10. A contact plug 32 is disposed within the dielectric layer 30 and contacts one of the source/drain regions 22.

The method of fabricating the high voltage MOS transistor illustrated in FIG. 1 and FIG. 2 includes the following steps. First, as shown in FIGS. 1 and 2, a substrate 12 is provided. Then, isolation region 24 including isolation elements 24a/24b is formed within the substrate 12 to define an active region. Next, a well 14 is formed within the substrate. The well 14 may be formed by performing an ion implantation process to implant n-type or p-type dopants in the substrate. After that, two drift regions 20 are formed within the well 14. The drift regions 22 can be formed by another ion implantation process. Later, a mask layer such as silicon nitride is formed on the substrate 12 to work with the isolation region 24 to define the position of a gate dielectric layer 18. Then, an oxidation process is performed to form a gate dielectric layer 18 on the well 14. The gate dielectric layer 18 overlaps part of the drift region 20. Subsequently, the mask layer is removed. Next, a gate 16 is formed on the gate dielectric layer 18. The gate 16 can be formed by depositing a conductive material over the gate dielectric layer 18 and followed by a photolithographic and etching process. Later, source/drain regions 22 are respectively formed within each of the drift regions 20. Each of the source/drain regions 22 is disposed between one of the isolation elements 24a and one of the isolation elements 24b. Finally, the pickup region 26 may be formed at one side of each isolation element 24b. The source/drain regions 22 and the pickup region 26 may be formed by their respective implantation processes. It is noted worthy that the position of the gate dielectric layer 18 is defined by the isolation region 24. A region 101 of the substrate 12 under the gate 16 is surrounded and defined by the isolation region 24, wherein the region 101 entirely overlaps the gate dielectric layer 18. The current 28 is generated within the region 101 and between the substrate 12 and the gate dielectric layer 18.

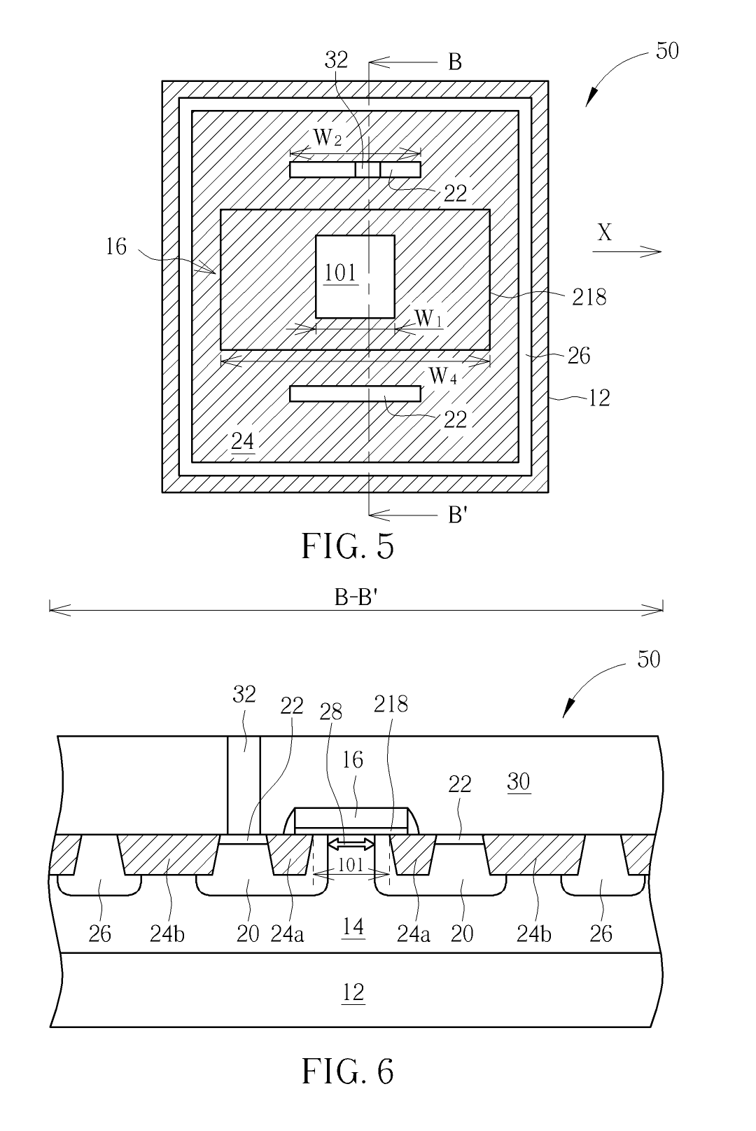

FIG. 5 depicts schematically a top view of a high voltage transistor according to a second preferred embodiment of the present invention. FIG. 6 is a cross-sectional view taken along line B-B′ of the high voltage transistor in FIG. 5. In FIG. 5 and FIG. 6, elements which are substantially the same as those in FIG. 1 and FIG. 2 are denoted by the same reference numerals; an accompanying explanation is therefore omitted. The difference between FIG. 1 and FIG. 5 is that the width W₁ of the gate dielectric layer 18 in FIG. 1 is smaller than the width W₂ of the source/drain region 22 and the width W₄ of the gate dielectric layer 218 in FIG. 5 is larger than the width W₂ of the source/drain region 22. Because the gate dielectric layer 18 in FIG. 1 is preferably made by an oxidation process, and the gate dielectric layer 218 in FIG. 5 is preferably made by a deposition process. Therefore, the size of the gate dielectric layer 18 in FIG. 1 equals to that of the region 101, and the size of the gate dielectric layer 218 in FIG. 5 may be larger than the size of the region 101. Furthermore, the gate dielectric layer 218 in FIG. 5 preferably has the same size as the gate 16.

The width W₁ of the gate dielectric layer 18 in FIG. 1 equals to the width W₁ of the region 101. By controlling the width W₁ of the region 101 to be smaller than the width W₂ of the source/drain region 22, the total current generated by the high voltage transistor can be controlled. In this way, as long as the width W₁ of the region 101 is smaller than the width W₂ of the source/drain region 22, the width W₄ of the gate dielectric layer 218 can be adjusted arbitrarily.

Therefore, the width W₄ of the gate dielectric layer 218 can have width W₄ larger than the width W₂ of the source/drain region 22. In detail, the gate dielectric layer 218 entirely overlaps the gate 16; however, only the gate dielectric layer 218 at the region 101 contacts the substrate 12. The current 28 is only generated within the region 101.

Kirk effect often happens in high voltage devices having a gate width smaller than 3 μm. The reason for the Kirk effect may originate from the current density and the dopant concentration of the drift region being similar. When the current density and the dopant concentration of the drift region are similar, current breakdown happens between the source/drain region and the drift region, raising the current density. As a result, when the operational voltage increases, the current density of the high voltage device becomes unstable. The currently density is the total current divided by the width of the source/drain region. One of the concepts of the present invention is to lower the total current by reducing the width of the gate dielectric layer, while retaining the conventional width of the source/drain region. Therefore, the current density can be reduced.

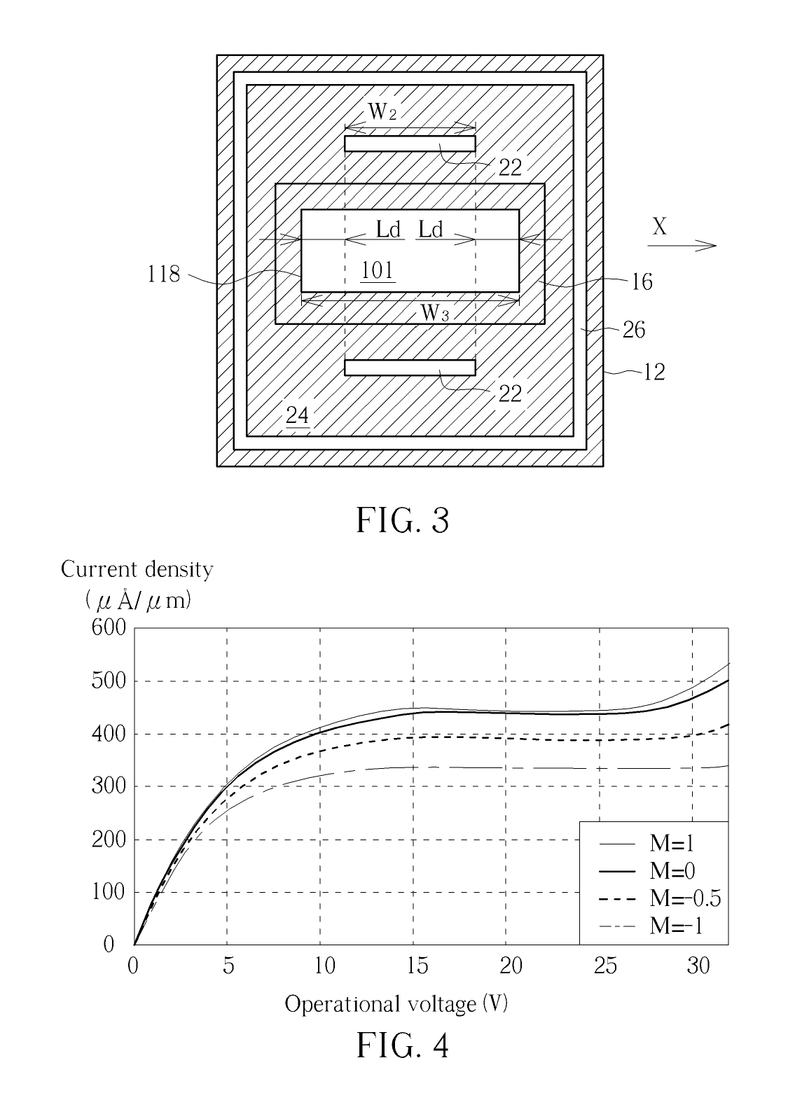

FIG. 3 shows a top view of high voltage devices with gate dielectric layers of different widths. FIG. 4 is a graph of current density vs. operational voltage for high voltage transistors with gate dielectric layers of different widths.

The difference between FIG. 1 and FIG. 3 is that the width of the gate dielectric layer in FIG. 3 varies. In FIG. 3, elements which are substantially the same as those in FIG. 1 are denoted by the same reference numerals; an accompanying explanation is therefore omitted. Furthermore, in FIG. 3, Ld equals ⅓ the width of the source/drain region. The gate dielectric layer 118 in FIG. 3 is also made by an oxidation process. As the width W₃ of the gate dielectric layer 118 in FIG. 3 varies, the size of the region 101 varies by altering the size of the isolation region 24 to make the region 101 entirely overlap the gate dielectric layer 118.

As shown in FIG. 4, there are four curves which show current density vs. operational voltage when the width W₃ of the gate dielectric layer 118 changes at four different multiples of Ld. M represents the multiple of Ld. When M equals 0, which means the Ld equals 0, the width W₃ of the gate dielectric layer 118 is the same as the width W₂ of the source/drain region 22. The two ends of the gate dielectric layer 118 are aligned with two ends of the source/drain region 22. Two dotted lines show the alignment of the two ends of the gate dielectric layer 118. When M equals 1, the width W₃ of the gate dielectric layer 118 increases to ⅓ of the width W₂ of the source/drain region 22 from each dotted line. When M equals −0.5, the width W₃ of the gate dielectric layer 118 decreases to ⅙ of the width W₂ of the source/drain region 22 from each dotted line. When M equals −1, the width W₃ of the gate dielectric layer 118 decreases to ⅓ of the width W₂ of the source/drain region 22 from each dotted line. As shown in FIG. 4, when M equals 1, which means the width W₃ of the gate dielectric layer 118 is larger than the width W₂ of the source/drain region 22, the current density raises suddenly as the operational voltage reaches 30 volts. When M equals −1, which means the width W₃ of the gate dielectric layer 118 is smaller than the width W₂ of the source/drain region 22, the current density is stable as the operational voltage reaches 30 volts. Therefore, making the width W₃ of the gate dielectric layer 118 smaller than the width W₂ of the source/drain region 22 can effectively prevent the Kirk effect.

Those skilled in the art will readily observe that numerous modifications and alterations of the device and method may be made while retaining the teachings of the invention. Accordingly, the above disclosure should be construed as limited only by the metes and bounds of the appended claims.

1: A high voltage transistor, comprising:
a substrate;
a well, disposed within the substrate;
a gate, disposed on the well;
a gate dielectric layer, disposed between the well and the gate, wherein a width of the gate is greater than a width of the gate dielectric layer;
two drift regions respectively disposed in the well at two sides of the gate;
two source/drain regions respectively disposed within each drift region, wherein a width of the gate dielectric layer is smaller than a width of the source/drain region; and
two isolation elements respectively disposed within each drift region.

2: The high voltage transistor of claim 1, wherein each drift region encloses one of the source/drain regions and one of the isolation elements.

3: The high voltage transistor of claim 1, further comprising a channel region disposed directly under the gate dielectric layer and between the drift regions.

4: The high voltage transistor of claim 1, wherein the gate extends along a direction, and wherein the width of the source/drain region and the width of the gate dielectric layer also extends along the direction.

5: The high voltage transistor of claim 1, wherein the well is a first conductive type, the drift regions are a second conductive type, and the source/drain regions are the second conductive type.

6: The high voltage transistor of claim 5, wherein a dopant concentration of the second conductive type in the drift regions is smaller than a dopant concentration of the second conductive type in the source/drain regions.

7: The high voltage transistor of claim 6, wherein a dopant concentration of the second conductive type in the drift regions is between 1E12˜8E12 cm⁻².

8: The high voltage transistor of claim 6, wherein a dopant concentration of the second conductive type in the source/drain regions is between 1E14 and 1E15 cm⁻².

9: The high voltage transistor of claim 5, wherein the first conductive type is P conductive type and the second conductive type is N conductive type.

10: The high voltage transistor of claim 5, wherein the first conductive type is N conductive type and the second conductive type is P conductive type.

11: The high voltage transistor of claim 1, further comprising a contact plug contacting one of the source/drain regions.

12: A high voltage transistor, comprising:
a substrate;
an isolation region, disposed within the substrate to define a region;
a well, disposed within the substrate;
a gate, disposed on the well and above the region, wherein a width of the gate is greater than a width of the region;
a gate dielectric layer disposed between the well and the gate, wherein the region entirely overlaps the gate dielectric layer;
two drift regions respectively disposed in the well at two sides of the gate; and
two source/drain regions respectively disposed within each drift region, wherein the width of the region is smaller than a width of the source/drain region.

13: A high voltage transistor, comprising:
a substrate;
an isolation region, disposed within the substrate to define a region;
a well, disposed within the substrate;
a gate, disposed on the well and above the region;
a gate dielectric layer overlapping the region and disposed between the well and the gate;
two drift regions respectively disposed in the well at two sides of the gate; and
two source/drain regions respectively disposed within each drift region, wherein a width of the region is smaller than a width of the source/drain region and a width of the gate is greater than the width of the source/drain region.
